(19) United States
(12) Patent Application Publication
(10) Pub. No.: US 2022/0129154 A1
(43) Pub. Date: Apr. 28, 2022

(54) MANAGING BIN PLACEMENT FOR BLOCK FAMILIES OF A MEMORY DEVICE USING TRIGGER METRIC SCORES

(71) Applicant: MICRON TECHNOLOGY, INC., Boise, ID (US)

(72) Inventors: Shane Nowell, Boise, ID (US); Mustafa N. Kaynak, San Diego, CA (US)

(21) Appl. No.: 17/077,953

(22) Filed: Oct. 22, 2020

(51) Int. Cl. G06F 3/06

(52) U.S. Cl. CPC G06F 3/064; G06F 3/0679; G06F 3/0653; G06F 3/0604

(57) ABSTRACT

An example processing device of a memory sub-system is configured to select, from a plurality of voltage bins associated with a memory device, a first set of voltage bins, wherein each voltage bin is associated with a corresponding set of read level offsets; determine, based on a trigger metric associated with the first set of bins, a first score of the first set of bins; replace at least a first voltage bin of the first set with at least a second voltage bin of the plurality of voltage bins to generate a second set of voltage bins; determine a second score of the second set of voltage bins; and responsive to determining that the second score of the second set of bins is greater than the first score of the first set of voltage bins, utilize the second set of voltage bins for performing read operations of the memory device.

### TECHNICAL FIELD

Embodiments of the disclosure are generally related to memory sub-systems, and more specifically, are related to managing bin placement for block families of a memory device, using trigger metric scores.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1 illustrates an example computing system that includes a memory sub-system in accordance with some embodiments of the present disclosure.

FIG. 2 schematically illustrates the temporal voltage shift caused by the slow charge loss exhibited by triple-level memory cells, in accordance with some embodiments of the present disclosure.

FIG. 3 depicts an example graph illustrating the dependency of the threshold voltage offset on the time after program (i.e., the period of time elapsed since the block had been programmed, in accordance with some embodiments of the present disclosure.

FIG. 4 schematically illustrates a set of predefined threshold voltage bins, in accordance with embodiments of the present disclosure.

FIG. 5 schematically illustrates block family management operations implemented by the block family manager component of the memory-sub-system controller operating in accordance with embodiments of the present disclosure.

FIG. 6 schematically illustrates selecting block families for calibration, in accordance with embodiments of the present disclosure.

FIG. 7 schematically illustrates example metadata maintained by the memory sub-system controller for associating blocks and/or partitions with block families, in accordance with embodiments of the present disclosure.

FIG. 8 depicts a sequence diagram illustrating the flow of events for an example method 800 of generating a set of placed voltage bins by selecting voltage bins from an initial set of proto bins and replacing one voltage bin at a time, in accordance with one or more aspects of the present disclosure.

FIG. 9 depicts a sequence diagram illustrating the flow of events for another example method 900 of generating a set of placed voltage bins by selecting voltage bins from an initial set of proto bins and replacing two voltage bin at a time, in accordance with some embodiments of the present disclosure.

FIG. 10 is a flow diagram of an example method of managing bin placement for block families of a memory device using trigger metric scores associated with placed bins, in accordance with some embodiments of the present disclosure.

FIG. 11 is a flow diagram of an example method of scoring placed bins by shifting one bins at a time using a variable number of shifting steps for each bin, in accordance with some embodiments of the present disclosure.

FIG. 12 is a block diagram of an example computer system in which embodiments of the present disclosure can operate.

### DETAILED DESCRIPTION

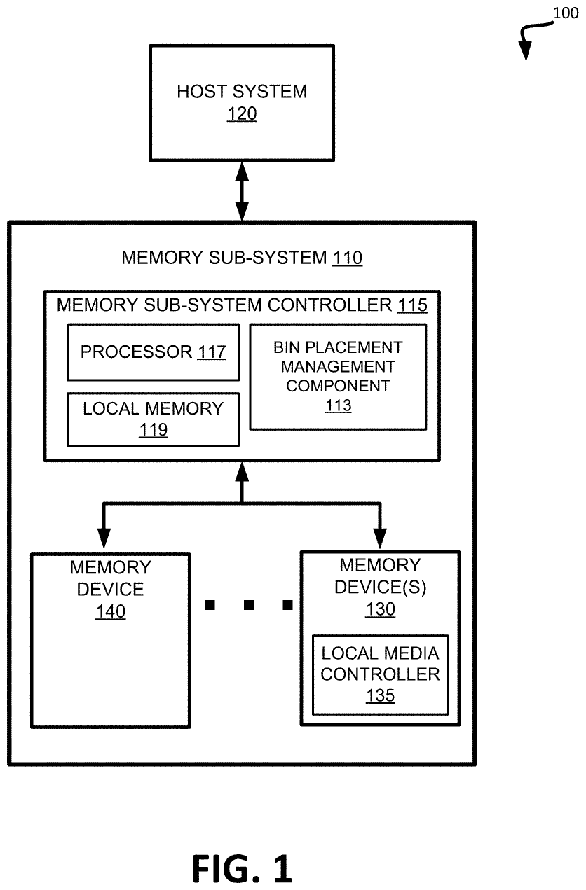

Embodiments of the present disclosure are directed to managing bin placement for block families of a memory device. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can utilize one or more memory devices, including any combination of the different types of non-volatile memory devices and/or volatile memory devices, to store the data provided by the host system. In some embodiments, non-volatile memory devices can be provided by negative-and (NAND) type flash memory devices. Other examples of non-volatile memory devices are described below in conjunction with FIG. 1. A non-volatile memory device is a package of one or more dice. Each die can consist of one or more planes. Planes can be groups into logic units (LUN). For some types of non-volatile memory devices (e.g., NAND devices), each plane consists of a set of physical blocks. A “block” herein shall refer to a set of contiguous or non-contiguous memory pages. An example of “block” is “erasable block,” which is the minimal erasable unit of memory, while “page” is a minimal writable unit of memory. Each page includes of a set of memory cells. A memory cell is an electronic circuit that stores information.

Data operations can be performed by the memory sub-system. The data operations can be host-initiated operations. For example, the host system can initiate a data operation (e.g., write, read, erase, etc.) on a memory sub-system. The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data”. A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., ECC codeword, parity code), data version (e.g. used to distinguish age of data written), valid bitmap (which LBAs or logical transfer units contain valid data), etc.

A memory device includes multiple memory cells, each of which can store, depending on the memory cell type, one or more bits of information. A memory cell can be programmed (written to) by applying a certain voltage to the memory cell, which results in an electric charge being held by the memory cell, thus allowing modulation of the voltage distributions produced by the memory cell. Moreover, precisely controlling the amount of the electric charge stored by the memory cell allows to establish multiple threshold voltage levels corresponding to different logical levels, thus effectively allowing a single memory cell to store multiple bits of information: a memory cell operated with 2° different threshold voltage levels is capable of storing n bits of information. “Read Threshold voltage” herein shall refer to the voltage level that defines a boundary between two neighboring voltage distributions corresponding to two logical levels. Thus, the read operation can be performed by comparing the measured voltage exhibited by the memory cell to one or more reference voltage levels in order to distinguish between two logical levels for single-level cells and between multiple logical levels for multi-level cells.

Due to the phenomenon known as slow charge loss (SCL), the threshold voltage of a memory cell changes in time as the electric charge of the cell is degrading, which is referred to as “temporal voltage shift” (since the degrading electric charge causes the voltage distributions to shift along the voltage axis towards lower voltage levels). The threshold voltage is changing rapidly at first (immediately after the memory cell was programmed), and then slows down in an approximately logarithmic linear fashion with respect to the time elapsed since the cell programming event. Accordingly, failure to mitigate the temporal voltage shift caused by the slow charge loss can result in the increased bit error rate in read operations.

However, various common implementations either fail to adequately address the temporal voltage shift or employ inefficient strategies resulting in high bit error rates and/or exhibiting other shortcomings. Embodiments of the present disclosure address the above-noted and other deficiencies by implementing a memory sub-system that employs block family based error avoidance strategies, thus significantly improving the bit error rate exhibited by the memory sub-system. In accordance with embodiments of the present disclosure, the temporal voltage shift is selectively tracked for programmed blocks grouped by block families, and appropriate voltage offsets, which are based on block affiliation with a certain block family, are applied to the base read levels in order to perform read operations. “Block family” herein shall refer to a possibly noncontiguous set of memory cells (which can reside in one or more full and/or partial blocks, the latter referred to as “partitions” herein) that have been programmed within a specified time window and a specified temperature window, and thus are expected to exhibit similar or correlated changes in their respective data state metrics for SCL. A block family may be made with any granularity, containing only whole codewords, whole pages, whole super pages, or whole superblocks, or any combination of these. Given that wear-leveling keeps program/erase cycles similar on all blocks, the time elapsed after programming and temperature are the main factors affecting the temporal voltage shift. Accordingly, all blocks and/or partitions within a single block family are presumed to exhibit similar distributions of threshold voltages in memory cells, and thus would require the same voltage offsets to be applied to the base read levels for read operations. “Base read level” herein shall refer to read threshold voltage level per valley exhibited by the memory cell immediately after programming or after a pre-determined time after programming. In some implementations, base read levels can be stored in the metadata of the memory device.

Block families can be created asynchronously with respect to block programming events. In an illustrative example, a new block family can be created whenever a specified period of time (e.g., a predetermined number of minutes) has elapsed since creation of the last block family or the reference temperature of memory cells has changed by more than a specified threshold value. The memory sub-system controller can maintain an identifier of the active block family, which is associated with one or more blocks as they are being programmed.

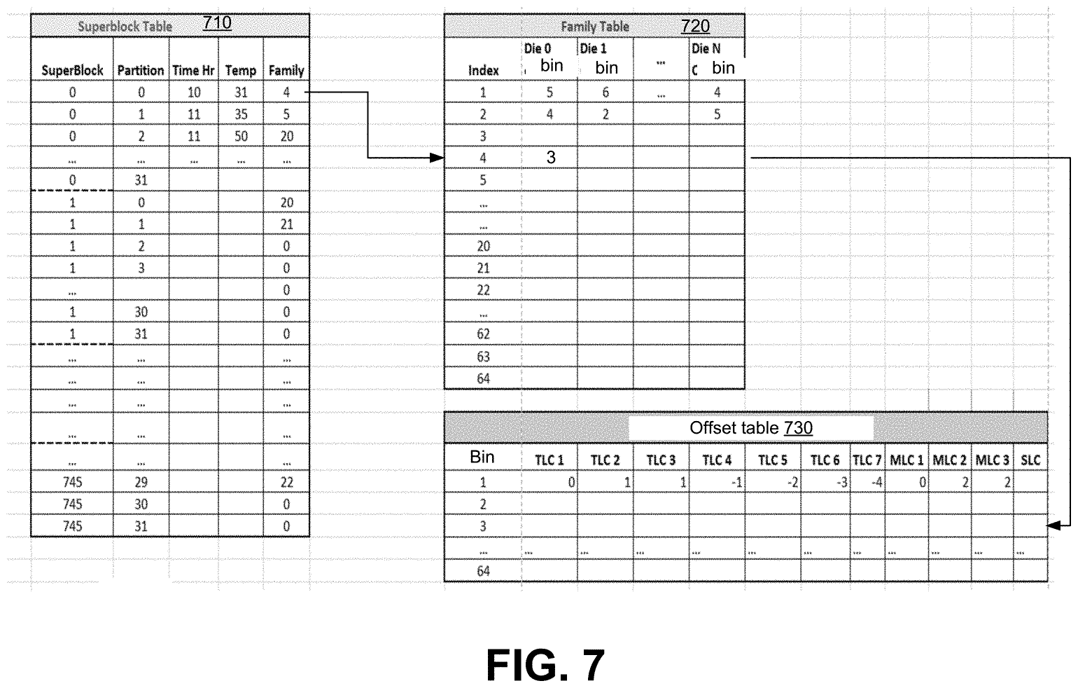

The memory sub-system controller can periodically perform a calibration process in order to associate each die of every block family with one of the predefined threshold voltage bins, which is in turn associated with the voltage offsets to be applied for read operations. In certain implementations, each voltage bin has one offset per valley, where each valley is a distance between two adjacent data states. For example, for TLC blocks storing 3 bits, there can be 8 data states (i.e., levels) and 7 valleys. Hence each voltage bin for TLC blocks has 7 offsets one for each valley. In some implementations, reads can be associated with pages and each page type corresponds to certain valleys. For the page reads, appropriate offsets are read from the bin the block family has been assigned to. The one or more valleys of each page type are determined by the Gray code used to represent the levels. Gray code refers to a binary numeral system were two successive valleys differ in only one bit (e.g., binary digit). On TLC blocks, some parts of the block can be multi-level cell (MLC) storing 2 bits per memory cell (resulting in 4 data states), or single level cell (SLC) storing 1 bit per memory cell. For MLC and SLC parts, there can be 3 and 1 offset respectively. Offset Table 730 in FIG. 7 captures examples of possible cases of TLC, MLC, SLC. The associations of blocks with block families and block families and dies with threshold voltage bins can be stored in respective metadata tables maintained by the memory sub-system controller.

More specifically, the present disclosure addresses the ability to generate a set of placed bins for the memory device, using scores of trigger metrics of the placed bins. Placing voltage bins using trigger metric scores provides the advantage of efficiently and automatically placing bins with time and/or temperature while maintaining minimum bin spacing between adjacent bins. Trigger metric refers to a measurement indicating the extent to which a memory device can enter error recovery due to non-correctable cells of the memory device. In one implementation, trigger metric can be a trigger rate representing the percentage of codewords with high error rates of the memory device that are not correctable when read outside of an error handling process. The high error rates can be due to using wrong offsets bins, due to assigning the block to a wrong bin, or because the offsets within a bin being sub-optimal. The score of a given set of voltage bins refers to a variance between a trigger metric associated with the set from a trigger metric threshold, such that the higher the score the farther the memory device from an error recovery state.

In accordance with embodiments of the present disclosure, a set of initial voltage bins can be generated, from which a subset of placed bins can be selected for bin placement within the memory sub-system. Each bin of the initial voltage bins can be associated with read level offsets that can be used for read operations of blocks associated with the bin. While each bin can be associated with multiple read level offsets, a representative page type with associated read level offsets can be used for the purpose of determining a trigger metric based on the read operation. In an embodiment, the initial set of voltage bins can be generated such the read level offsets of the bins for each valley are equally spaced within the voltage distribution of threshold voltages. A base set of voltage bins can be selected from the initial set of voltage bins such that a score can be determined for the base set of voltage bins. The score can be determined based on a trigger metric associated with a number of representative page type read operations using read level offsets of the base set of voltage bins. Certain bins from the base set of bins can be replaced and a score after each replacement can be determined, such that the set of voltage bins that generates the highest score can be designated as the set of placed bins associated with the memory device and can be used when performing read operations of blocks of the memory device. When replacing bins within the base set of voltage bins, the number of bins to be replaced in each cycle can vary from one cycle to the next. Additionally, the number of steps to use when replacing bins can be increased and/or decreased and a corresponding score can be determined until a set of placed bins with a highest possible score is determined, as explained in more details herein below.

Therefore, advantages of the systems and methods implemented in accordance with some embodiments of the present disclosure include, but are not limited to, optimizing the bin placement process within time based on a scoring algorithm that ranks each variations of possible sets of placed bins. The set of placed bin are selected based on an optimization algorithm that identifies the optimal set of placed bins that can result in successful read operations of the memory device with minimal error handling or repeated reads. Because the bin placement process also maintains a minimum spacing between adjacent bins, the overhead of moving block families from one bin to the next over time is minimized. Additionally, the present disclosure provides an automatic process for placing bins without requiring human effort for manual placement.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device (e.g., a processor).

The computing system 100 can include a host system 120 that is coupled to one or more memory sub-systems 110. In some embodiments, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory devices such as 3D cross-point array of non-volatile memory cells and NAND type memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the controller 115, in another embodiment of the present disclosure, a memory sub-system 110 does not include a controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

In some implementations, memory sub-system 110 can use a striping scheme, according to which every the data payload (e.g., user data) utilizes multiple dies of the memory devices 130 (e.g., NAND type flash memory devices), such that the payload is distributed through a subset of dies, while the remaining one or more dies are used to store the error correction information (e.g., parity bits). Accordingly, a set of blocks distributed across a set of dies of a memory device using a striping scheme is referred herein to as a “superblock.”

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

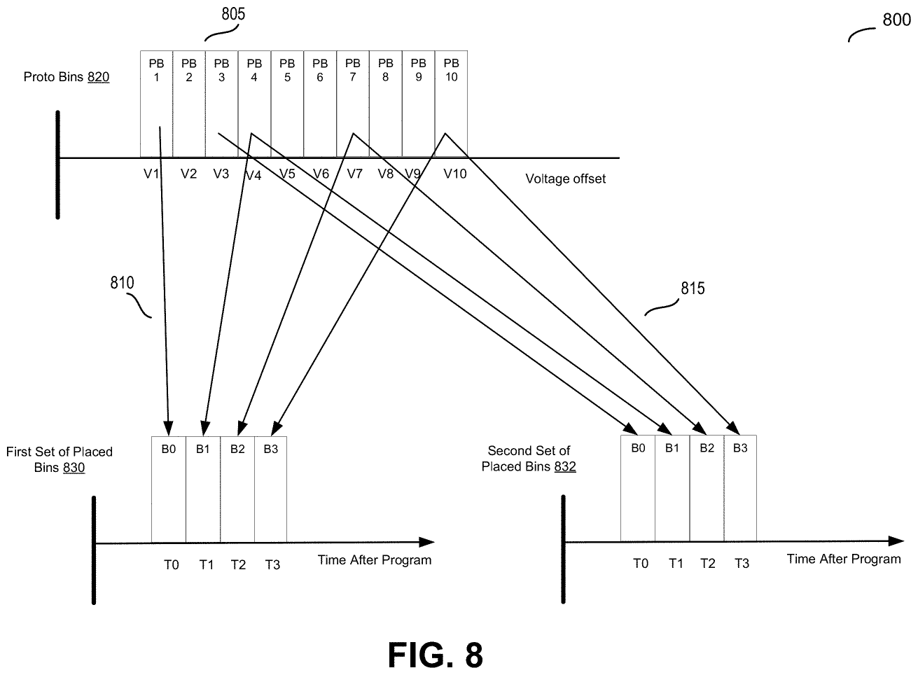

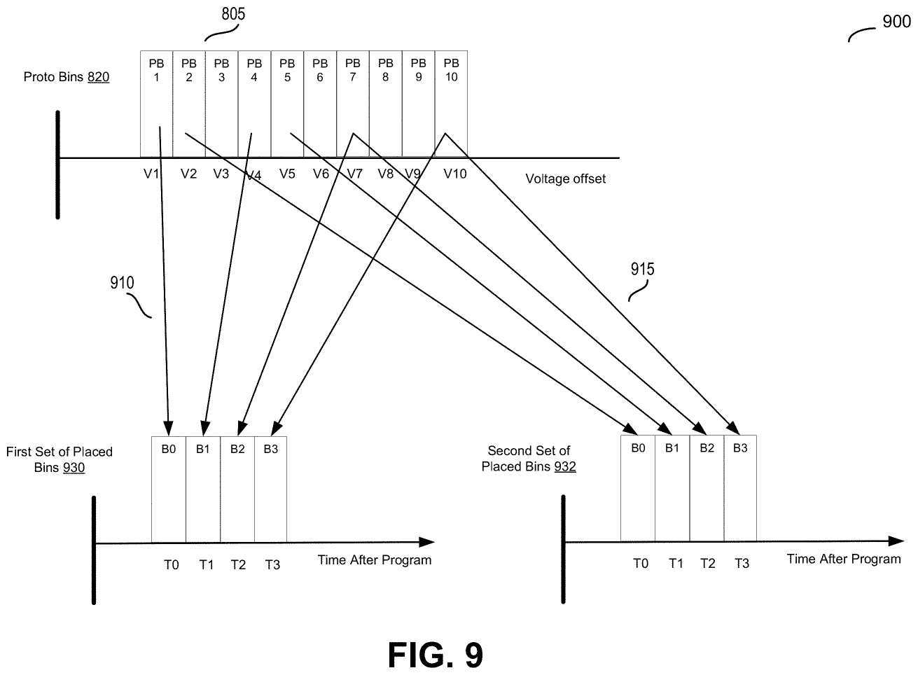

The memory sub-system 110 includes a bin placement management component 113, which can be used to implement techniques for selecting voltage bins for read operations based on optimized trigger metric scores of the selected voltage bins within memory sub-system 110, in accordance with embodiments of the present disclosure. In some embodiments, bin placement management component 113 can generate a set of initial voltage bins from which a subset of bins can be selected for bin placement within memory sub-system 110. Each bin of the initial voltage bins can be associated with read level offsets that can be used for read operations of blocks associated with the bin corresponding to a particular SCL region. In an implementation, the initial set of voltage bins can be generated such that the read level offsets for a given valley are equally spaced within bins (e.g., the read level offset of a given valley in the initial voltage bins is 2 DACs apart from the read level offset of an adjacent bin for the same valley). For different read level offsets, the DAC increment can be different given that the SCL slope for each valley is different. For example, higher levels experience more SCL compared to lower levels. When the initial set of voltage bins is generated, bin placement management component 113 can select a base set of voltage bins from the initial set of voltage bins and can determine a score for the base set of voltage bins. In an embodiment, the base set of voltage bins can be a subset of the initial set of voltage bins, such that the number of steps between each adjacent voltage bins of the base set of voltage bins is approximately equal. Each step represents an adjacent bin of the initial set of voltage bins for a specific valley, as illustrated in FIGS. 8-9.

Bin placement management component 113 can determine a score corresponding to the base set of voltage bins, based on a trigger metric associated with the base set of voltage bins. In order to determine the score associated with the base set of voltage bins, bin placement management component 113 can perform a number of read operations of one or more blocks of memory at predetermined periods of time (e.g., time slices) using read level offsets associated with the base set of voltage bins. For example, each read operation can be performed using a read level offsets of one of the voltage bins from the base set of voltage bins. The read operation can be for the representative page type. Bin placement management component 113 can then determine a trigger metric associated with the base set of voltage bins, based on the performed read operations. As an example, bin placement management component 113 can determine a trigger metric associated with each read operation, based on the read level offsets used for the read operation and then determine a trigger metric associated with the base set of voltage bins by calculating an average of the trigger metric values of all read operations. In another example, bin placement management component 113 can determine the trigger metric associated with the base set of voltage bins by calculating a different metric of the trigger metric values, other than the average (e.g., the means of the trigger metric values, the median of the trigger metric values, or any other formula). Bin placement management component 113 can then determine a score based on the trigger metric of the base set of voltage bins. In an embodiment, the score can be a variance of the trigger metric from a certain trigger metric threshold, such that the score is higher when the trigger metric is far from the threshold and lower when the trigger metric is close to the threshold.

After determining a score for the base set of voltage bins, bin placement management component 113 can start a process of replacing bins within the base set, thus generating new sets of voltage bins, determining a score for each set, and then selecting the set with the highest score as the set of placed voltage bins. Bin placement management component 113 can associate the set of placed voltage bins with the memory device. Block families of the memory device can then be assigned to the placed voltage bins of the memory device, based on the time after program (TAP) of each block family, along with other factors, as explained in more details herein below.

In one implementation, bin placement management component 113 can replace one voltage bin from the base set of voltage bins at a time, calculate a new score after replacing each bin, and keep the bin with the higher score. In this case, bin placement management component 113 can replace each bin with a number of possible bins, and only keep the bin resulting in a higher score for the base set of voltage bins. In an illustrative example, bin placement management component 113 can replace the first bin of the base set of voltage bins with another bin from the initial set of voltage bins that is separated from the first bin by 4 steps for a representative valley. Bin placement management component 113 can then perform a read operation using the replaced bin and determine a score corresponding to a trigger metric of the read operation. Bin placement management component 113 can then replace the same bin of the base set of voltage bins with another bin from the initial set of voltage bins that is separated from the first bin by 2 steps for a representative valley, and can similarly perform a read operation and determine a score corresponding to the new bin. Bin placement management component can also perform the same process after replacing the first bin with another bin that is separated from the first bin by only 1 step for a representative valley, and determine a corresponding score for the new bin. Given the three scores corresponding to the three replacements of the first bin, bin placement management component 113 can select the bin with the highest score as the replacement to the first bin of the base set of voltage bins. Bin placement management component 113 can proceed to perform the same process for each other bin in the base set of voltage bins (e.g., replacing each bin with another bin that is 4 steps away, then another bin that is 2 steps away, and so on, and keep the bin with the highest score). In certain implementations, bin replacement management component 113 can perform the replacement using a different number of steps and/or for a different number of iterations than the numbers illustrated in this example. When each bin of the base set of voltage bins is evaluated for replacement, bin placement management component 113 can determine that the base set of voltage bins now has the highest possible score, and can designate the base set as the set of placed voltage bins of the memory device.

In another implementation, bin placement management component 113 can replace two voltage bins from the base set of voltage bins simultaneously, calculate a new score of the base set after replacing the two bins, and keep the set with the higher score. Bin placement management component 113 can then replace three voltage bins from the base set of voltage bins simultaneously and calculate a corresponding score. Next, bin placement management components can replace four bins and calculate a corresponding score, and so on. In this case, bin placement management component 113 can keep the number of steps the same, as the number of bins to be replaced increase. For example, bin placement management component 113 can replace two voltage bins from the base set of voltage bins with another two voltage bins that are 4 steps away from each of the two bins for a representative valley. When replacing three bins simultaneously, bin placement management component 113 can replace three voltage bins from the base set of voltage bins with another three voltage bins that are 4 steps away from each of the three bins for a representative valley, respectively, and so. In one implementation, after replacing a variable number of bins simultaneously and keeping the set with the higher score after each replacement, bin placement management component 113 can change the number of steps to use when replacing each bin of the base set of voltage bin (e.g., use 2 steps instead of 4 steps), and then repeat the process of modifying the number of bins to be replaced simultaneously. Similarly, bin placement management component 113 can keep the set with the higher score after each round of bin replacements. When each bin of the base set of voltage bins is evaluated for replacement, bin placement management component 113 can determine that the base set of voltage bins now has the highest possible score, and can designate the base set as the set of placed voltage bins of the memory device.

In yet another implementation, bin placement management component 113 can increase the number of bins to be replaced while also changing the number of steps with which each bin can be shifted. In an illustrative example, bin placement management component 113 can first select one bin to be replaced, and can replace the one bin with another bin from the initial set of voltage bins that is separated from the bin by 4 steps for a representative valley and determine a corresponding score. Bin placement management component 113 can then select another bin that is separated from the bin by 2 steps for a representative valley and determine a corresponding score, and so on. When the bin is replaced with other bins at all possible distances and a bin associated with the highest score is selected, bin placement management component 113 can then replace two bins simultaneously, such that each bin of the two bins is replaced with another bin that is 4 steps away for a representative valley, and determine a corresponding score. Subsequently, bin placement management component 113 can then replace the two bins with another two bins that are 2 steps away, and so. In this case, when the optimization algorithm is modifying the number of bins to be replaced in an outer loop, while modifying the number of steps to move to find a bin replacement in an inner loop, the algorithm can reach the highest score faster than the case where only the number of bins or the number of steps is being modified at a time. In certain implementations, in order to further optimize the replacement algorithm, bin placement management component 113 can reduce the number of steps as the number of bins to be replaced increases, such that when more bins are being replaced simultaneously, a fewer number steps can be attempted in order to find the highest possible score. As an example, bin placement management component 113 can replace one bin with another bin that is 4 steps away for a representative valley, then replace the one bin with another bin that is 2 steps away for a representative valley, followed by replacing the one bin with a third bin that is 1 step away for a representative valley and can select the bin that result in the highest score. One the other hand, when replacing 4 bins simultaneously, bin placement management component 113 can replace each of the four bins with another bin that is 1 step away for a representative valley, determine a corresponding score, and then proceed to replace another set of 4 bins and so.

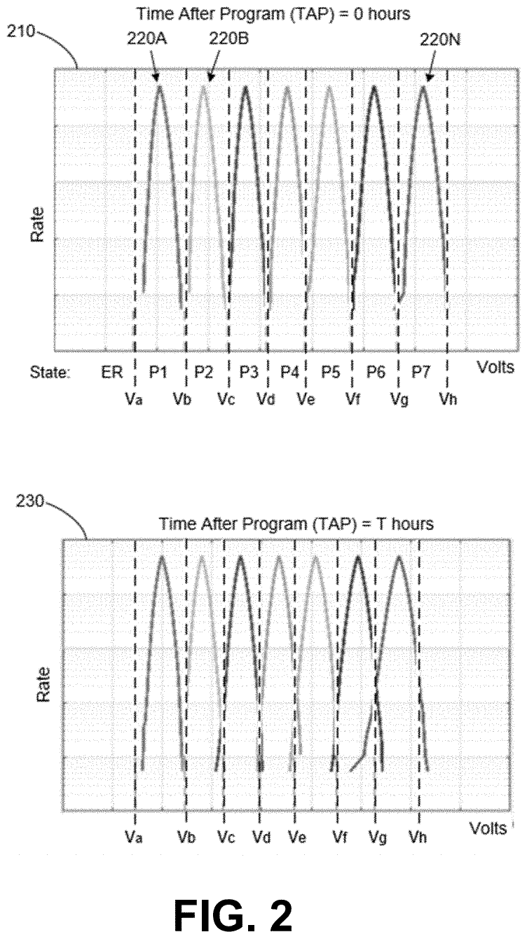

FIG. 2 illustrates the temporal voltage shift caused at least in part by the slow charge loss exhibited by triple-level memory cells, in accordance with embodiments of the disclosure. While the illustrative example of FIG. 2 utilizes triple-level cells, the same observations can be made and, accordingly, the same remedial measures are applicable to single level cells and any memory cells having multiple levels.

A memory cell can be programmed (written to) by applying a certain voltage (e.g. program voltage) to the memory cell, which results in an electric charge stored by the memory cell. Precisely controlling the amount of the electric charge stored by the memory cell allows a memory cell to have multiple threshold voltage levels that correspond to different logical levels, thus effectively allowing a single memory cell to store multiple bits of information. A memory cell operated with 2° different threshold voltage levels is capable of storing n bits of information.

Each of chart 210 and 230 illustrate program voltage distributions 220A-420N (also referred to as “program distributions” or “voltage distributions” or “distributions” or “levels” herein) of memory cells programmed by a respective write level (which can be assumed to be at the midpoint of the program distribution) to encode a corresponding logical level. The program distributions 220A through 220N can illustrate the range of threshold voltages (e.g., normal distribution of threshold voltages) for memory cells programmed at respective write levels (e.g., program voltages). In order to distinguish between adjacent program distributions (corresponding to two different logical levels), the read threshold voltage levels (shown by dashed vertical lines) are defined, such that any measured voltage that falls below a read threshold level is associated with one program distribution of the pair of adjacent program distributions, while any measured voltage that is greater than or equal to the read threshold level is associated with another program distribution of the pair of neighboring distributions.

In chart 210, eight states of the memory cell are shown below corresponding program distributions (except for the state labeled ER, which is an erased state, for which a distribution is not shown). Each state corresponds to a logical level. The read threshold voltage levels are labeled Va-Vh. As shown, any measured voltage below Va is associated with the ER state. The states labeled P1, P2, P3, P4, P5, P6, and P7 correspond to distributions 22A-220N, respectively.

Time After Program (TAP) herein shall refer to the time since a cell has been written and is the primary driver of TVS (temporal voltage shift). TVS captures SCL as well as other charge loss mechanisms. TAP can be estimated (e.g., inference from a data state metric), or directly measured (e.g., from a controller clock). A cell, block, page, block family, etc. is young (or, comparatively, younger) if it has a (relatively) small TAP and is old (or, comparatively, older) if it has a (relatively) large TAP. A time slice is a duration between two TAP points during which a measurement can be made (e.g., perform reference calibration from X to Y minutes or hours after program). A time slice can be referenced by its center point.

As seen from comparing example charts 210 and 230, which reflect the time after programming (TAP) of 0 (immediately after programming) and the TAP of T hours (where T is a number of hours), respectively, the program distributions change over time due primarily to slow charge loss. In order to reduce the read bit error rate, the corresponding read threshold voltages are adjusted to compensate for the shift in program distributions, which are shown by dashed vertical lines. In various embodiments of the disclosure, the temporal voltage shift is selectively tracked for die groups based on measurements performed at one or more representative dice of the die group. Based on the measurements made on representative dice of a die group that characterize the temporal voltage shift and operational temperature of the dice of the die group, the read threshold voltage offsets used to read the memory cells for the dice of the die group are updated and are applied to the base read threshold levels to perform read operations.

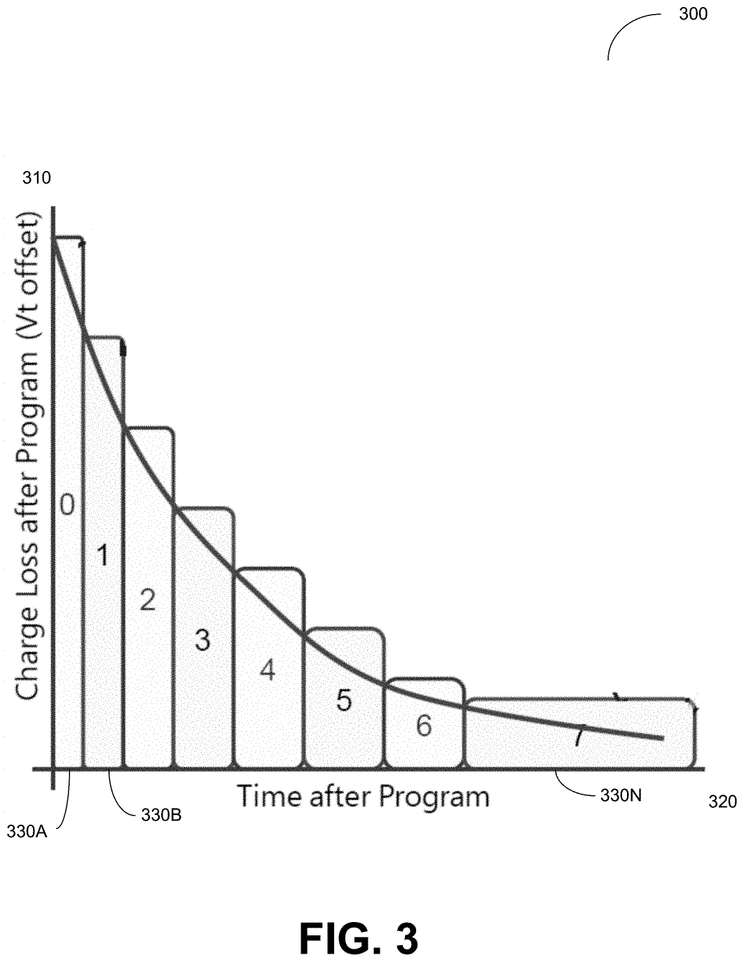

FIG. 3 depicts an example graph 300 illustrating the dependency of the threshold voltage offset 310 on the time after program 320 (i.e., the period of time elapsed since the block had been programmed. As schematically illustrated by FIG. 3, blocks of the memory device are grouped into block families 330A-330N, such that each block family includes one or more blocks that have been programmed within a specified time window and a specified temperature window. As noted herein above, given that wear-leveling can keep program/erase cycles similar on all blocks, the time elapsed after programming and temperature are the main factors affecting the temporal voltage shift. Accordingly, all blocks and/or partitions within block family 310 are presumed to exhibit similar distributions of threshold voltages in memory cells, and thus would require the same voltage offsets to be applied to the base read levels for read operations.

Block families can be created asynchronously with respect to block programming events. In an illustrative example, the memory sub-system controller 115 of FIG. 1 can create a new block family whenever a specified period of time (e.g., a predetermined number of minutes) has elapsed since creation of the last block family or whenever the reference temperature of memory cells, which is updated at specified time intervals, has changed by more than a specified threshold value since creation of the current block family.

A newly created block family can be associated with bin 0. Then, the memory sub-system controller can periodically perform a foreground or background calibration process in order to associate each die of every block family with one of the predefines threshold voltage bins (bins 0-7 in the illustrative example of FIG. 3), which is in turn associated with the voltage offsets to be applied for read operations. The associations of blocks with block families and block families and dies with threshold voltage bins can be stored in respective metadata tables maintained by the memory sub-system controller.

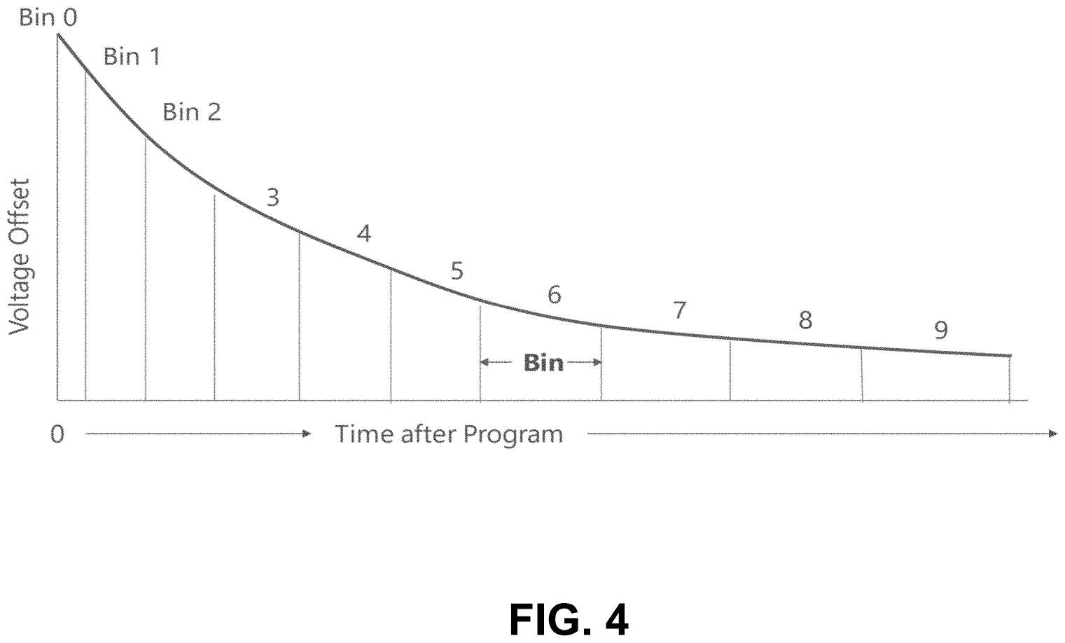

FIG. 4 schematically illustrates a set of placed threshold voltage bins (bin 0 to bin 9), in accordance with embodiments of the present disclosure for a selected valley. In an implementation, the set of placed bins can be determined based on the bin placement process described in FIG. 8. As schematically illustrated by FIG. 4, the threshold voltage offset graph can be subdivided into multiple threshold voltage bins, such that each bin corresponds to a predetermined range of threshold voltage offsets. While the illustrative example of FIG. 4 defines ten bins, in other implementations, various other numbers of bins can be employed (e.g., 64 bins). Based on a periodically performed calibration process, the memory sub-system controller associates each die of every block family with a threshold voltage bin, which defines a set of threshold voltage offsets to be applied to the base voltage read level in order to perform read operations, as described in more detail herein below.

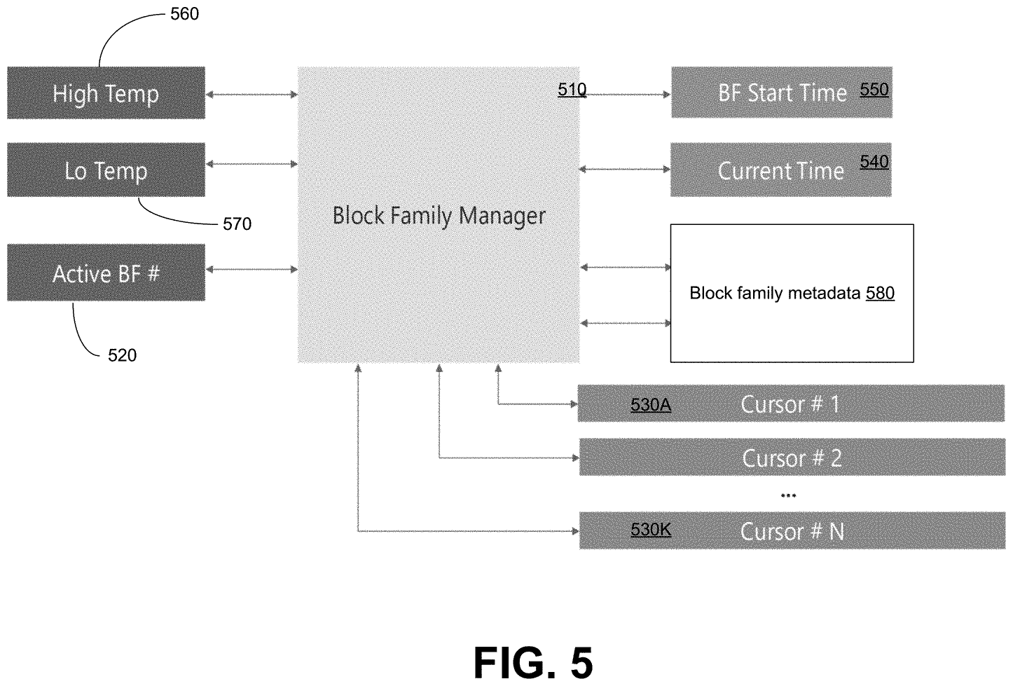

FIG. 5 schematically illustrates block family management operations implemented by the block family manager component of the memory-sub-system controller operating in accordance with embodiments of the present disclosure. As schematically illustrated by FIG. 5, the block family manager 510 can maintain, in a memory variable, an identifier 520 of the active block family, which is associated with one or more blocks of cursors 530A-530K as they are being programmed. “Cursor” herein shall broadly refer to a location on the memory device to which the data is being written.

The memory sub-system controller can utilize a power on minutes (POM) clock for tracking the creation times of block families. In some implementations, a less accurate clock, which continues running when the controller is in various low-power states, can be utilized in addition to the POM clock, such that the POM clock is updated based on the less accurate clock upon the controller wake-up from the low-power state.

Thus, upon initialization of each block family, the current time 540 is stored in a memory variable as the block family start time 550. As the blocks are programmed, the current time 540 is compared to the block family start time 550. Responsive to detecting that the difference of the current time 540 and the block family start time 550 is greater than or equal to the specified time period (e.g., a predetermined number of minutes), the memory variable storing the active block family identifier 520 is updated to store the next block family number (e.g., the next sequential integer number), and the memory variable storing the block family start time 550 is updated to store the current time 540.

The block family manager 510 can also maintain two memory variables for storing the high and low reference temperatures of a selected die of each memory device. Upon initialization of each block family, the high temperature 560 and the low temperature 570 variable store the value of the current temperature of the selected die of the memory device. In operation, while the active block family identifier 520 remains the same, temperature measurements are periodically obtained and compared with the stored high temperature 560 and the low temperature 570 values, which are updated accordingly: should the temperature measurement be found to be greater than or equal to the value stored by the high temperature variable 560, the latter is updated to store that temperature measurement; conversely, should the temperature measurement be found to fall below the value stored by the low temperature variable 570, the latter is updated to store that temperature measurement.

The block family manager 510 can further periodically compute the difference between the high temperature 560 and the low temperature 570. Responsive to determining that the difference between the high temperature 560 and the low temperature 570 is greater than or equal to a specified temperature threshold, the block family manager 510 can create a new active block family: the memory variable storing the active block family identifier 520 is updated to store the next block family number (e.g., the next sequential integer number), the memory variable storing the block family start time 550 is updated to store the current time 540, and the high temperature 560 and the low temperature 570 variables are updated to store the value of the current temperature of the selected die of the memory device.

At the time of programming a block, the memory sub-system controller associates the block with the currently active block family. The association of each block with a corresponding block family is reflected by the block family metadata 580, as described in more detail herein below with reference to FIG. 7.

As noted herein above, based on a periodically performed calibration process, the memory sub-system controller associates each die of every block family with a threshold voltage bin, which defines a set of threshold voltage offsets to be applied to the base voltage read level in order to perform read operations. The calibration process involves performing, with respect to a specified number of selected blocks within the block family that is being calibrated, read operations utilizing different threshold voltage offsets, and choosing the bin that minimizes the error rate of the read operation. The block within the block family can be randomly selected, or selected based on satisfying a specific criterion (such as being oldest in the block family).

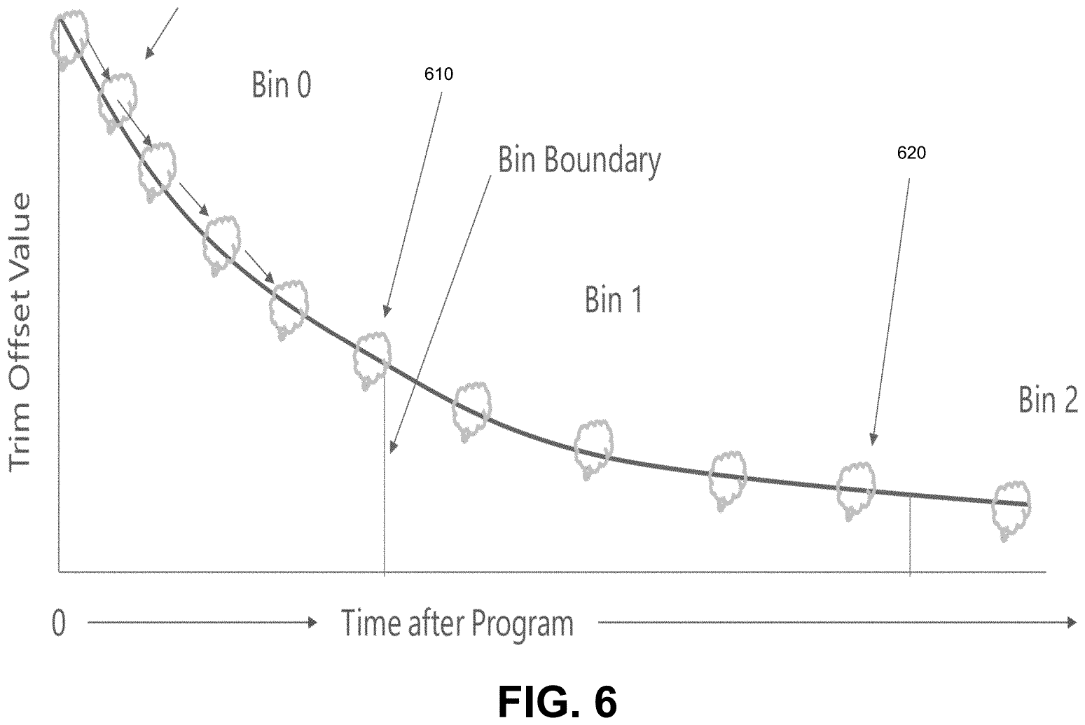

FIG. 6 schematically illustrates selecting block families for calibration, in accordance with embodiments of the present disclosure. As schematically illustrated by FIG. 6, the memory sub-system controller can limit the calibration operations to the oldest block family in each bin (e.g., block family 610 in bin 0 and block family 620 in bin 1), since it is the oldest block family that will, due to the slow charge loss, migrate to the next bin before any other block family of the current bin.

FIG. 7 schematically illustrates example metadata maintained by the memory sub-system controller for associating blocks and/or partitions with block families, in accordance with embodiments of the present disclosure. As schematically illustrated by FIG. 7, the memory sub-system controller can maintain the superblock table 710, the family table 720, and the offset table 730.

Each record of the superblock table 710 specifies the block family associated with the specified superblock and partition combination. In some implementations, the superblock table records can further include time and temperature values associated with the specified superblock and partition combination.

The family table 720 is indexed by the block family number, such that each record of the family table 720 specifies, for the block family referenced by the index of the record, a set of threshold voltage bins associated with respective dies of the block family. In other words, each record of the family table 720 includes a vector, each element of which specifies the threshold voltage bin associated with the die referenced by the index of the vector element. The threshold voltage bins to be associated with the block family dies can be determined by the calibration process, as described in more detail herein above.

Finally, the offset table 730 is indexed by the bin number. Each record of the offset table 730 specifies a set of threshold voltage offsets (e.g., for TLC, MLC, and/or SLC) associated with threshold voltage bin.

When combining two block families, e.g., by merging the blocks of a first block family into a second block family, then deleting the first block family, the metadata tables 710-730 can be updated as a result of combining the two block families. For example, that superblock table 710 can be updated to reflect that superblock and partition combinations of the first block family should be associated with the second block family. Similarly, the family table 720 can be updated to delete a record associated with the first block family from family table 720.

The metadata tables 710-730 can be stored on one or more memory devices 130 of FIG. 1. In some implementations, at least part of the metadata tables can be cached in the local memory 119 of the memory sub-system controller 115 of FIG. 1.

In operation, upon receiving a read command, the memory sub-system controller determines the physical address corresponding to the logical block address (LBA) specified by the read command. Components of the physical address, such as the physical block number and the die identifier, are utilized for performing the metadata table walk: first, the superblock table 710 is used to identify the block family identifier corresponding to the physical block number; then, the block family identifier is used as the index to the family table 720 in order to determine the threshold voltage bin associated with the block family and the die; finally, the identified threshold voltage bin is used as the index to the offset table 730 in order to determine the threshold voltage offset corresponding to the bin. The memory sub-system controller can then additively apply the identified threshold voltage offset to the base voltage read level in order to perform the requested read operation.

In the illustrative example of FIG. 7, the superblock table 710 maps partition 0 of the superblock 0 to block family 4, which is utilized as the index to the family table 720 in order to determine that die 0 is mapped to bin 3. The latter value is used as the index to the offset table in order to determine the threshold voltage offset values for bin 3.

FIG. 8 depicts a sequence diagram illustrating the flow of events for an example method 800 of generating a set of placed voltage bins by selecting voltage bins from an initial set of proto bins and replacing one voltage bin at a time, in accordance with one or more aspects of the present disclosure. Method 800 may be performed by processing logic that includes hardware (e.g., circuitry, dedicated logic, programmable logic, microcode, etc.), software (e.g., instructions run on a processor to perform hardware simulation), or a combination thereof. In some embodiments, the method 800 is performed by bin placement management component 113 of FIG. 1.

Method 800 starts at operation 805. At operation 805, the processing logic generates an initial set of bins, proto bins 820 that includes proto bins PB 1-PB 10. Each proto bin is associated with corresponding read level offsets V1(v)-V10(v) where v is index for the valleys, which can be used for read operations of blocks associated with the proto bin based on a page type, as explained in more details above. For TLC, there can be 7 valleys and hence each proto bin will have 7 offsets one for each valley such as TLC1-TLC7 in offset table 730 of FIG. 7. In 805 V1(v)-V10(v) are each a vector of 7 values for a TLC system. In an implementation, proto bins 820 can be generated such the read level offsets for a representative valley V1(v)-V10(v) are equally spaced within the voltage distribution of threshold voltages. As an example, each read level offset of V1(v)-V10(v) is 2 DACs apart from the adjacent read level offset for the representative valley. The representative valley can be selected to have the highest SCL signal which is usually the valley between two levels that have highest threshold voltages such as rightmost two voltage distributions in FIG. 2.

At operation 810, the processing logic can select a first set of placed bins 830 as a subset of proto bins 820. First set 830 can include four voltage bins: B0 as PB1 of proto bins 820, B1 as PB4 of proto bins 820, B2 as PB7 of proto bins 820, and B3 as PB10 of proto bins 820. In this case, the processing logic selects B0-B3 such that the distance between each selected bin and the adjacent bin is 3 steps (e.g., B0 refers to PB1, which is 3 steps away on the voltage distribution from B1 that refer to PB4 for the representative valley). The processing logic can then determine a score for first set of placed bins 830. As an example, the processing logic can perform a number of read operations of one or more blocks of memory at predetermined periods of time using read level offsets associated with B0-B3 respectively. The processing logic can then determine a trigger metric based on the read operations, for example by calculating an average of the trigger metric values associated with read level offsets of all read operations, or any other formula, as explained in more details herein above. The processing logic can then determine a score based on the trigger metric of first set of placed bins 830. The score can be indicative of an error level associated with the read level offsets of the voltage bins within first set of placed bins 830. For example, the score can be a variance of the trigger metric from a certain trigger metric threshold, such that the score is higher when the trigger metric is far from the threshold and lower when the trigger metric is close to the threshold.

After determining a score for the first set of placed bins 830, the processing logic, at operation 815, can decide to shift bin B0 by replacing PB1 with PB3 as B0 in second set of placed bins 832. In this case, the processing logic replaces PB1 with another bin that is 2 steps away from PB1 (i.e., PB3) for the representative valley and assign PB3 as B0 of the second set of placed bins 832. The processing logic can maintain the other three bins B1-B3 from first set of placed bins 830 with the same selected proto bins PB4, PB7, and PB10 respectively. Similarly, the processing logic can then determine a second score for second set of placed bins 832, by performing a number of read operations of one or more blocks of memory at predetermined periods of time using read level offsets associated with B0-B3 of second set of placed bins 832. The processing logic can then identify the set of placed bins with the higher score between first set of placed bind 830 and second set of placed bins 832 and designate the set with the higher score as the set of placed bins associated with the memory device, as explained in more details above.

FIG. 9 depicts a sequence diagram illustrating the flow of events for another example method 900 of generating a set of placed voltage bins by selecting voltage bins from an initial set of proto bins and replacing two voltage bins at a time, in accordance with some embodiments of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 900 is performed by the bin placement management component 113 of FIG. 1. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

Method 900 starts at operation 805. At operation 805, the processing logic generates an initial set of bins, proto bins 820 that includes proto bins PB 1-PB 10. Each proto bin is associated with a corresponding read level offset V1(v)-V10(v), which can be used for read operations of blocks associated with the proto bin. In an implementation, proto bins 820 can be generated such the read level offsets V1(v)-V10(v) are equally spaced within the voltage distribution of threshold voltages for the representative valley. As an example, each read level offset of V1-V10 is 2 DACs apart from the adjacent read level offset for the representative valley.

At operation 910, the processing logic can select a first set of placed bins 930 as a subset of proto bins 820, as explained above with respect to operation 810 of FIG. 8. First set 930 can include four voltage bins: B0 as PB1 of proto bins 820, B1 as PB4 of proto bins 820. As stated above, the processing logic can determine a score corresponding to first set of placed bins 930.

After determining a score for the first set of placed bins 930, the processing logic, at operation 915, can decide to shift two bins from first set 930, in order to determine if a higher score can be obtained. As an example, the processing logic can shift bin B0 by replacing PB1 with PB2 as B0 in second set pf placed bins 932 and shift bin B1 by replacing PB4 with PB5 as B1 in second set pf placed bins 932. In this case, the processing logic replaces PB1 with another bin that is one step away from PB1 (i.e., PB2) and assign PB2 as B0 of the second set of placed bins 932, and replace PB4 with another bin that is one step away from PB4 (i.e., PB5) and assign PB5 as B1 of the second set of placed bins 932. The processing logic can maintain the other two bins B2-B3 from first set of placed bins 930 with the same selected proto bins PB7, and PB10 respectively. Similar to determining a score for first set of placed bins 930, the processing logic can then determine a second score for second set of placed bins 932, by performing a number of read operations of one or more blocks of memory at predetermined periods of time using read level offsets associated with B0-B3 of second set of placed bins 932. The processing logic can then identify the set of placed bins with the higher score between first set of placed bind 930 and second set of placed bins 932 and designate the set with the higher score as the set of placed bins associated with the memory device, as explained in more details above.

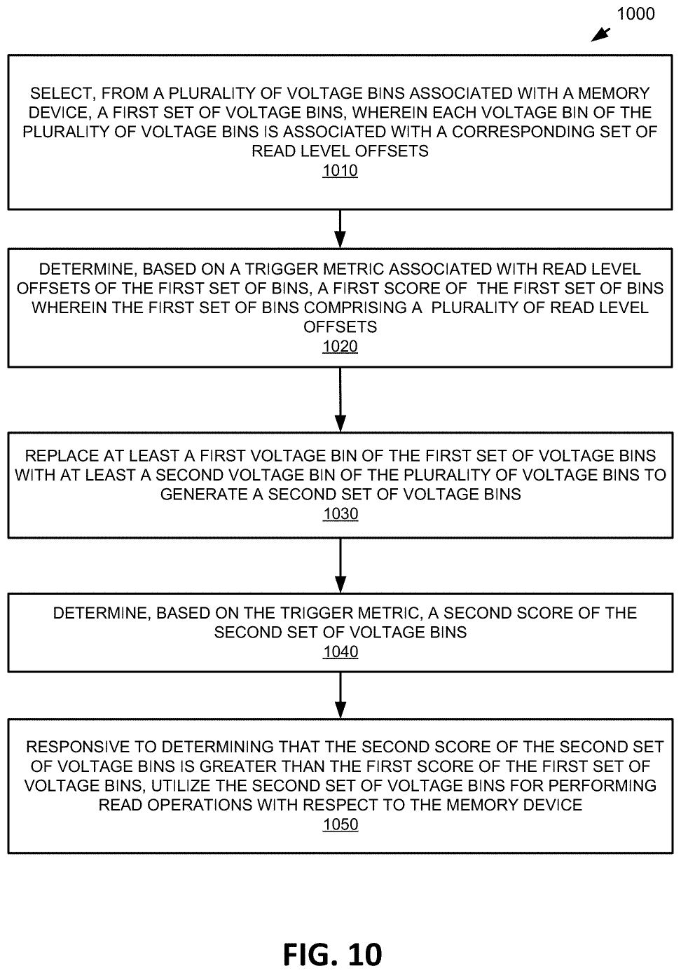

FIG. 10 is a flow diagram of an example method of managing bin placement for block families of a memory device using trigger metric scores associated with placed bins, in accordance with some embodiments of the present disclosure. The method 1000 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 1000 is performed by the bin placement management component 113 of FIG. 1. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At operation 1010, the processing logic starts the process of selecting placed bins from an initial set of bins. The processing logic selects, from a group of initial voltage bins associated with a memory device, a first set of voltage bins, whereas each voltage bin of the initial set of voltage bins is associated with corresponding read level offsets, one for each valley. In implementations, the read level offsets of the initial set of voltage bins for each valley can be equally spaced within the voltage space of threshold voltages, and the initial set of bins can have more bins than a target number of placed bins, as explained in more details herein.

At operation 1020, the processing logic determines, based on a trigger metric associated with read level offsets of the first set of bins, a first score of the first set of bins. For example, the trigger metric can be a trigger rate indicating the extent to which the memory device should go into error recovery due to non-correctable cells of the memory device, as explained in more details herein above. The first score can be a variance of the trigger metric from a certain trigger metric threshold, such that the higher the score the farther the memory device from error recovery state, based on the determined trigger metric.

At operation 1030, the processing logic replaces one or more voltage bins of the first set of voltage bins with one or more voltage bins of the initial set of voltage bins to generate a second set of voltage bins. At operation 1040, the processing logic determines, based on the trigger metric of the second set of voltage bins, a second score of the second set of voltage bins. In an example, the processing logic can determine the second score by performing a number of read operation using the read level offsets of the second set of voltage bins and determine a trigger metric associated with the read operations, as explained in more details herein above.

At operation 1050, responsive to determining that the second score of the second set of voltage bins is greater than the first score of the first set of voltage bins, the processing logic can utilize the second set of voltage bins for performing read operations for reading data stored at blocks of the memory device.

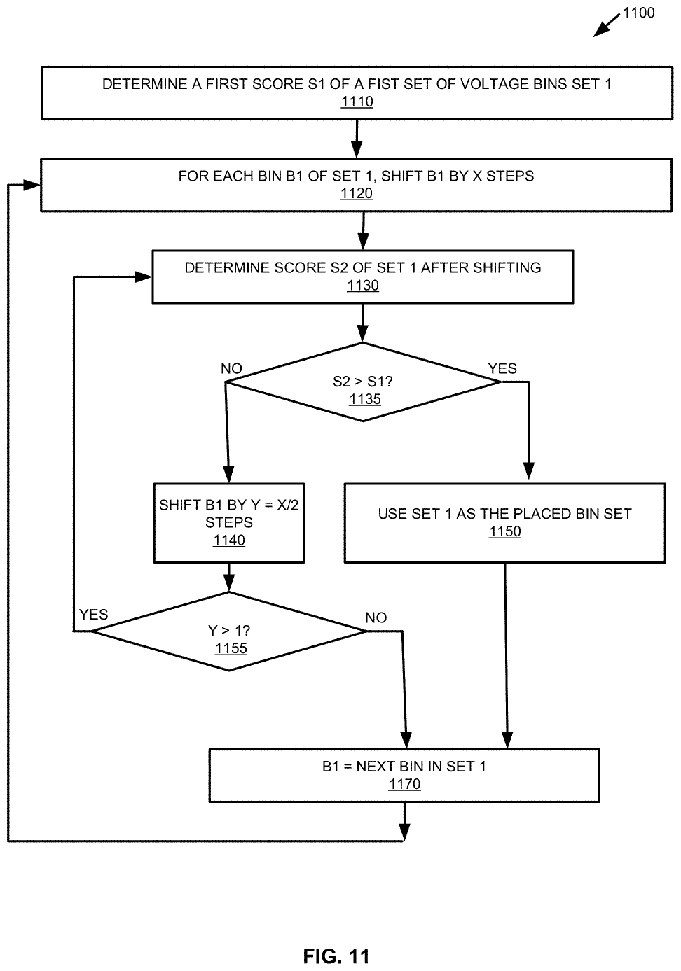

FIG. 11 is a flow diagram of an example method of scoring placed bins by shifting one bins at a time using a variable number of shifting steps for each bin, in accordance with some embodiments of the present disclosure. The method 1100 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 1100 is performed by the bin placement management component 113 of FIG. 1. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At operation 1110, the processing logic determines a first set of voltage bins SET1 of a memory device and determines a first score S1 corresponding to SET1, as explained above. The processing logic can then determine to replace each bin within SET1, one bin at a time, determine a corresponding score after replacing each bin and utilize the set with the highest score as the placed bin set of the memory device.

At operation 1120, the processing logic can loop through each bin B1 of SET1 and can shift B1 by a certain number of steps within a set of proto bins associated with the memory device. As an example, the processing logic can replace B1 with another bin that is 4 steps away from B1 within the set of proto bins of the memory device.

At operation 1130, the processing logic can determine a score S2 of SET1 after shifting B1. In implementations, the processing logic can generate a second set SET2 (not shown) after shifting each bin and can determine score S2 of SET2. At operation 1135, the processing logic can determine whether S2 is greater than S1. If S2 is greater than S1, the processing logic, at operation 1150, can utilize SET 1 that includes the shifted B1 as the placed bin set of the memory device. The processing logic can then proceed to operation 1170 to evaluate another bin of bin set SET1.

At operation 1140, when the processing logic determines that S2 is less than or equal to S1, the processing logic can decrease the number of steps for shifting B1 and can determine a new score S2 based on the bin associated with the decreased steps. The processing logic can continue to determine a score after decreasing the shift size (e.g., by diving the latest number of steps by 2) until a corresponding score S2 that is higher than S1 is found or until the number of steps reaches one. At operation 1155, when the processing logic determines that the number of steps is less than one, the processing logic can determine to move to the next bin of SET1, at operation 1170, and can continue to shift the new B1 using the variable step sizes and preserving the set with the highest score with each iteration. The processing logic can continue to evaluate each bin within SET1, one bin at a time, until all bins are evaluated for replacement. When each bin of SET1 is evaluated, the placed bin set can include the set of bins with the heist scores from all the iterations. The processing logic can then associated the placed bin set with the memory device, to be used for assigning block families and performing read operations of data stored at the memory device, as explained in more details herein above.

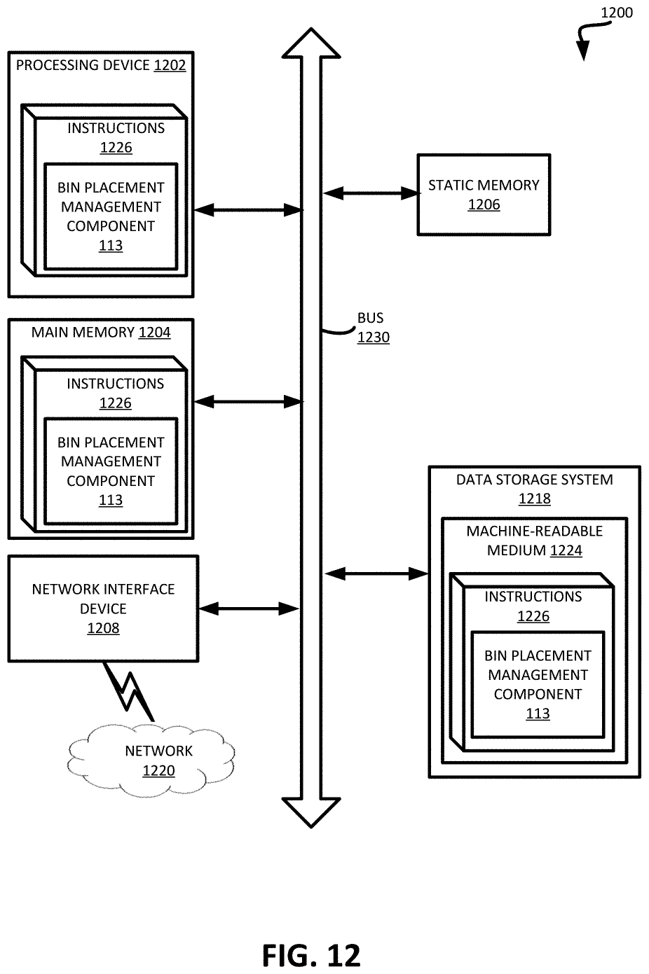

FIG. 12 illustrates an example machine of a computer system 1200 within which a set of instructions, for causing the machine to perform any one or more of the methodologies discussed herein, can be executed. In some embodiments, the computer system 1200 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to bin placement management component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1200 includes a processing device 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), etc.), and a data storage system 1218, which communicate with each other via a bus 1230.

Processing device 1202 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1202 can also be one or more special-purpose processing devices such as an application specific integrated circuit (ASIC), a field programmable gate array (FPGA), a digital signal processor (DSP), network processor, or the like. The processing device 1202 is configured to execute instructions 1226 for performing the operations and steps discussed herein. The computer system 1200 can further include a network interface device 1208 to communicate over the network 1220.

The data storage system 1218 can include a machine-readable storage medium 1224 (also known as a computer-readable medium) on which is stored one or more sets of instructions 1226 or software embodying any one or more of the methodologies or functions described herein. The instructions 1226 can also reside, completely or at least partially, within the main memory 1204 and/or within the processing device 1202 during execution thereof by the computer system 1200, the main memory 1204 and the processing device 1202 also constituting machine-readable storage media. The machine-readable storage medium 1224, data storage system 1218, and/or main memory 1204 can correspond to the memory sub-system 110 of FIG. 1.

In one embodiment, the instructions 1226 include instructions to implement functionality corresponding to bin placement management component 113 of FIG. 1. While the machine-readable storage medium 1224 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
selecting, from a plurality of voltage bins associated with a memory device, a first set of voltage bins, wherein each voltage bin of the plurality of voltage bins is associated with a corresponding set of read level offsets;
determining, based on a trigger metric associated with read level offsets of the first set of bins, a first score of the first set of bins wherein the first set of bins comprising a plurality of read level offsets;
replacing at least a first voltage bin of the first set of voltage bins with at least a second voltage bin of the plurality of voltage bins to generate a second set of voltage bins;
determining, based on a second trigger metric associated with the second set of voltage bins, a second score of the second set of voltage bins; and
responsive to determining that the second score of the second set of voltage bins is greater than the first score of the first set of voltage bins, utilizing the second set of voltage bins for performing read operations with respect to the memory device.

2. The method of claim 1 further comprising:
responsive to determining that the second score of the second set of voltage bins is less than the first score of the first set of voltage bins, utilizing the first set of voltage bins for performing read operations with respect to the memory device.

3. The method of claim 1 further comprising:
generating the plurality of voltage bins associated with the memory device, wherein read level offsets of the plurality of voltage bins for a representative valley are approximately equally spaced within a voltage space of threshold voltages associated with the memory device.

4. The method of claim 1, wherein the first set of voltage bins is a subset of the plurality of voltage bins, wherein a number of steps between each adjacent voltage bins of the first set of voltage bins is approximately equal, and wherein each step comprises a bin of the plurality of bins.

5. The method of claim 1 further comprising:
responsive to determining that the second score of the second set of voltage bins is less than the first score of the first set of voltage bins:
replacing at least a third voltage bin of the first set of voltage bins with at least a fourth voltage bin of the plurality of voltage bins to generate a third set of voltage bins;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

6. The method of claim 1 further comprising:
responsive to determining that the second score of the second set of voltage bins is less than the first score of the first set of voltage bins:
replacing the at least first voltage bin of the first set of voltage bins with at least a third voltage bin of the plurality of voltage bins to generate a third set of voltage bins, wherein a first number of steps between the third voltage bin and the first voltage bin is less than a second number of steps between the second voltage bin and the first voltage bin;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

7. The method of claim 1 further comprising:
responsive to determining that the second score of the second set of voltage bins is less than the first score of the first set of voltage bins:
replacing the at least first voltage bin of the first set of voltage bins with at least a third voltage bin of the plurality of voltage bins to generate a third set of voltage bins, wherein a first number of steps between the third voltage bin and the first voltage bin is less than a second number of steps between the second voltage bin and the first voltage bin;
replacing at least a fourth voltage bin of the third set of voltage bins with at least a fifth voltage bin of the plurality of voltage bins;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

8. The method of claim 1, wherein the trigger metric is a trigger rate representing a percentage of defective memory cells of the memory device.

9. The method of claim 1, wherein determining the first score of the first set of voltage bins further comprises:
performing a plurality of read operations at a corresponding plurality of periods of time, wherein the plurality of read operation are performed using read level offsets associated with the first set of voltage bins;
determining, based on the read operations, the trigger metric corresponding to the read level offsets associated with the first set of voltage bins; and
determining the first score of the first set of voltage bins based on the trigger metric.

10. The method of claim 8, wherein the first score corresponds to a variance between the trigger metric and a predefined trigger metric threshold.

11. A system comprising:
a memory device; and
a processing device, operatively coupled to the memory device, the processing device to perform operations comprising:
identifying a set of placed bins associated with a memory device, wherein the set of placed bins is associated with a first score based on a trigger metric corresponding to read level offsets of the set of placed bin;
replacing a subset of the voltage bins of the set of placed bins with an equivalent set of voltage bins of a plurality of voltage bins associated with the memory drive, to generate a second set of voltage bins;
determining, based on a second trigger metric of the second set of voltage bins, a second score of the second set of voltage bins; and
responsive to determining that the second score of the second set of voltage bins is greater than the first score of the first set of voltage bins, utilizing the second set of voltage bins for performing read operations with respect to the memory device.

12. The system of claim 11, wherein the first set of voltage bins is a subset of the plurality of voltage bins, wherein a number of steps between each adjacent voltage bins of the first set of voltage bins is approximately equal, and wherein each step comprises a bin of the plurality of bins.

13. The system of claim 11, responsive to determining that the second score of the second set of voltage bins is less than the first score of the first set of voltage bins:
replacing a second subset of the voltage bins of the set of placed bins with an equivalent second set of voltage bins of the plurality of voltage bins associated with the memory drive, to generate a third set of voltage bins;
determining, based on based on a third trigger metric of the third set of voltage bins, a third score of the third set of voltage bins; and
responsive to determining that the third score of the third set of voltage bins is greater than the first score of the first set of voltage bins, utilizing the third set of voltage bins for performing read operations with respect to the memory device.

14. The system of claim 11, wherein determining the second score of the second set of voltage bins further comprises:
performing a plurality of read operations at a corresponding plurality of periods of time, wherein the plurality of read operation are performed using read level offsets associated with the second set of voltage bins;
determining, based on the read operations, the second trigger metric corresponding to the read level offsets associated with the second set of voltage bins; and
determining the second score of the second set of voltage bins based on the trigger metric.

15. The system of claim 11, wherein the trigger metric is a trigger rate representing a percentage of defective memory cells of the memory device.

16. A non-transitory computer-readable storage medium comprising instructions that, when executed by a processing device, cause the processing device to perform operations comprising:
selecting, from a plurality of voltage bins associated with a memory device, a first set of voltage bins, wherein each voltage bin of the plurality of voltage bins is associated with a corresponding set of read level offset;
determining, based on a trigger metric associated with read level offsets of the first set of bins, a first score of the first set of bins wherein the first set of bins comprising a plurality of read level offsets;
replacing at least a first voltage bin of the first set of voltage bins with at least a second voltage bin of the plurality of voltage bins to generate a second set of voltage bins;
determining, based on a second trigger metric associated with the second set of voltage bins, a second score of the second set of voltage bins; and
responsive to determining that the second score of the second set of voltage bins is greater than the first score of the first set of voltage bins, utilizing the second set of voltage bins for performing read operations with respect to the memory device.

17. The non-transitory computer-readable storage medium of claim 16, wherein the processing device to perform further operations comprising:
responsive to determining that the second score of the second set of voltage bins is less than the first score of the first set of voltage bins:
replacing at least a third voltage bin of the first set of voltage bins with at least a fourth voltage bin of the plurality of voltage bins to generate a third set of voltage bins;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

18. The non-transitory computer-readable storage medium of claim 16, wherein the processing device to perform further operations comprising:
responsive to determining that the second score of the second set of voltage bins is less than the first score of the first set of voltage bins:
replacing the at least first voltage bin of the first set of voltage bins with at least a third voltage bin of the plurality of voltage bins to generate a third set of voltage bins, wherein a first number of steps between the third voltage bin and the first voltage bin is less than a second number of steps between the second voltage bin and the first voltage bin;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

19. The non-transitory computer-readable storage medium of claim 16, wherein the processing device to perform further operations comprising:
responsive to determining that the second score of the second set of voltage bins is less than the first score of the first set of voltage bins:
replacing the at least first voltage bin of the first set of voltage bins with at least a third voltage bin of the plurality of voltage bins to generate a third set of voltage bins, wherein a first number of steps between the third voltage bin and the first voltage bin is less than a second number of steps between the second voltage bin and the first voltage bin;
replacing at least a fourth voltage bin of the third set of voltage bins with at least a fifth voltage bin of the plurality of voltage bins;
determining, based on the trigger metric, a third score of the third set of voltage bins; and
responsive to determining that the third score of the third set of voltage bins is greater than the first score of the first set of voltage bins, utilizing the third set of voltage bins for performing read operations with respect to the memory device.

20. The non-transitory computer-readable storage medium of claim 16, wherein determining the first score of the first set of voltage bins further comprises:
performing a plurality of read operations at a corresponding plurality of periods of time, wherein the plurality of read operation are performed using read level offsets associated with the first set of voltage bins;
determining, based on the read operations, the trigger metric corresponding to the read level offsets associated with the first set of voltage bins; and
determining the first score of the first set of voltage bins based on the trigger metric.
